(19) United States
(12) Patent Application Publication
(10) Pub. No.: US 2019/0194493 A1
(43) Pub. Date: Jun. 27, 2019

(54) COMPOSITION FOR SEMICONDUCTOR TREATMENT AND TREATMENT METHOD

(71) Applicant: JSR CORPORATION, Minato-ku (JP)

(72) Inventors: Katsutaka YOKOI, Minato-ku (JP); Ken-ichi YAMAMOTO, (US); Ran MITSUBOSHI, Minato-ku (JP); Kanae MASUDA, Minato-ku (JP); Satoshi KAMO, Minato-ku (JP); Tomotaka SHINODA, Minato-ku (JP)

(73) Assignee: JSR CORPORATION, Minato-ku (JP)

(21) Appl. No.: 16/328,490

(22) PCT Filed: Jun. 27, 2018
(86) PCT No.: PCT/JP2018/024333

§ 371 Date: Feb. 26, 2019

(30) Foreign Application Priority Data
Aug. 3, 2017 (JP) 2017-150560

(51) Int. Cl. C09G 1/04; H01L 21/321; H01L 21/02; H01L 21/768

(52) U.S. Cl. CPC C09G 1/04; H01L 21/3212; H01L 21/76883; H01L 21/7684; H01L 21/02074

(57) ABSTRACT

Provided are a composition for semiconductor treatment capable of suppressing damage due to corrosion to wiring or the like including tungsten on an object to be treated, and efficiently removing contamination from a surface of the object to be treated, and a treatment method using the composition for semiconductor treatment. The treatment method includes a step of, after subjecting a wiring board including tungsten as a wiring material to chemical mechanical polishing using a composition containing an iron ion and a peroxide, subjecting the wiring board to treatment with a composition for semiconductor treatment which includes: a compound (A) having two or more of at least one selected from a group consisting of tertiary amino groups and salts thereof; and a water-soluble compound (B) having a solubility parameter of 10 or more, and which has a pH of from 2 to 7.

### TECHNICAL FIELD

The present invention relates to a composition for semiconductor treatment and a treatment method using the same.

### BACKGROUND ART

Chemical mechanical polishing (CMP) utilized for production of semiconductor devices is a technology involving pressing an object to be treated (an object to be polished) against a polishing pad, and causing the object to be treated and the polishing pad to slide with respect to each other while supplying an aqueous dispersion for chemical mechanical polishing (hereinafter also referred to simply as “CPM slurry”) onto the polishing pad, to thereby chemically and mechanically polish the object to be treated. The CMP slurry used for such CMP contains a chemical, such as an etching agent or a pH adjusting agent, as well as abrasive grains for polishing. Moreover, polishing scraps are generated through the CMP. When those polishing scraps remain on the object to be treated, a fatal device defect may occur. Therefore, a step of cleaning the object to be treated after the CMP is essential.

For example, a metal wiring material, such as copper or tungsten, an insulating material, such as silicon oxide, and a barrier metal material, such as tantalum nitride or titanium nitride, are exposed on a surface of the object to be treated after the CMP. When such materials of different types coexist on a polished surface, the polished surface is required to be treated so that only contamination is removed from the polished surface without causing damage, such as corrosion. For example, in Patent Literature 1, there is disclosed a technology for suppressing corrosion of a polished surface on which a wiring material and a barrier metal material are exposed through use of an acid composition for semiconductor treatment. In addition, for example, in each of Patent Literature 2 and Patent Literature 3, there is disclosed a technology involving treating a polished surface on which a wiring material and a barrier metal material, such as cobalt, are exposed with a neutral to alkaline composition for semiconductor treatment.

### CITATION LIST

### Patent Literature

PTL 1: JP 2010-258014 A

PTL 2: JP 2009-055020 A

PTL 3: JP 2013-157516 A

### SUMMARY OF INVENTION

### Technical Problem

However, in recent years, a circuit structure has become finer. Along with this, there is a demand for a treatment technology capable of further suppressing damage to metal wiring or the like on the object to be treated, and efficiently removing contamination from the surface of the object to be treated.

For example, in CMP of an object to be treated including tungsten as metal wiring, a CMP slurry containing iron nitrate and another oxidizing agent (hydrogen peroxide, potassium iodate, or the like) is used. An iron ion contained in the CMP slurry is liable to be adsorbed onto the surface of the object to be treated, and hence the surface of the object to be treated is liable to be contaminated with iron. In this case, the contamination with iron can be removed by treating the surface of the object to be treated with a composition including ammonia and hydrogen peroxide or dilute hydrofluoric acid. However, the surface of the object to be treated is liable to be corroded and suffer from damage. Therefore, there is a demand for a treatment technology capable of suppressing the damage due to corrosion to the metal wiring or the like on the object to be treated to the extent possible, and effectively removing contamination from the surface of the object to be treated.

In view of the foregoing, according to some aspects of the invention, there are provided a composition for semiconductor treatment capable of suppressing damage due to corrosion to wiring or the like including tungsten on an object to be treated, and efficiently removing contamination from a surface of the object to be treated by solving at least some of the above-mentioned problems, and a treatment method using the composition for semiconductor treatment.

### Solution to Problem

The invention has been made in order to solve at least some of the above-mentioned problems, and can be implemented as the following application examples.

### APPLICATION EXAMPLE 1

According to one embodiment of the invention, there is provided a treatment method including:

subjecting a wiring board containing tungsten as a wiring material to chemical mechanical polishing by using a composition containing an iron ion and a peroxide; and

subjecting the wiring board to a treatment which uses a composition for semiconductor treatment, the composition for semiconductor treatment having a pH of from 2 to 7 and containing a compound (A) having two or more of at least one selected from a group consisting of tertiary amino groups and salts thereof, and a water-soluble compound (B) having a solubility parameter of 10 or more.

### APPLICATION EXAMPLE 2

In the treatment method according to the above-mentioned application example, the treatment method may further include diluting the composition for semiconductor treatment by from 20 times to 500 times.

### APPLICATION EXAMPLE 3

In the treatment method according to any one of the above-mentioned application examples, the treatment method may further include adjusting a viscosity of the composition for semiconductor treatment at 25° C. to 5 mPa·s or less.

### APPLICATION EXAMPLE 4

In the treatment method according to any one of the above-mentioned application examples, the treatment method may further include filtering the composition for semiconductor treatment with a depth-type filter or a pleat-type filter.

### APPLICATION EXAMPLE 5

In the treatment method according to any one of the above-mentioned application examples,

subjecting the wiring board to a treatment which uses a composition for semiconductor treatment may include using any one of:

filling a cleaning bath with the composition for semiconductor treatment and dipping the wiring board thereinto;

rotating the wiring board at a high speed while causing the composition for semiconductor treatment to flow down to the wiring board from a nozzle; and

spraying the composition for semiconductor treatment on the wiring board to clean the wiring board.

### APPLICATION EXAMPLE 6

The treatment method according to any one of the above-mentioned application examples may include: subjecting the wiring board to a treatment using a physical force, as the step of subjecting the wiring board to a treatment which uses a composition for semiconductor treatment.

### APPLICATION EXAMPLE 7

The treatment method according to any one of the above-mentioned application examples may further include: cleaning the wiring board with ultrapure water or pure water.

### APPLICATION EXAMPLE 8

In the treatment method according to any one of the above-mentioned application examples, the water-soluble compound (B) may be a water-soluble polymer.

### APPLICATION EXAMPLE 9

In the treatment method according to any one of the above-mentioned application examples, the composition for semiconductor treatment may further contain at least one selected from a group consisting of organic acids and phosphoric acid.

### APPLICATION EXAMPLE 10

According to one embodiment of the invention, there is provided a composition for semiconductor treatment of a concentrated type to be used for treatment of a surface of an object to be treated having arranged thereon wiring containing tungsten, the composition for semiconductor treatment including:

a compound (A) having two or more of at least one selected from a group consisting of tertiary amino groups and salts thereof; and

a water-soluble compound (B) having a solubility parameter of 10 or more, and

the composition for semiconductor treatment having a pH of from 2 to 7.

### APPLICATION EXAMPLE 11

The composition for semiconductor treatment according to the above-mentioned application example may be used after being diluted by from 1 time to 500 times.

### APPLICATION EXAMPLE 12

According to one embodiment of the invention, there is provided a composition for semiconductor treatment of a non-dilution type to be used for treatment of a surface of an object to be treated having arranged thereon wiring containing tungsten, the composition for semiconductor treatment including:

a compound (A) having two or more of at least one selected from a group consisting of tertiary amino groups and salts thereof; and

a water-soluble compound (B) having a solubility parameter of 10 or more, and

the composition for semiconductor treatment having a pH of from 2 to 7.

### APPLICATION EXAMPLE 13

In the composition for semiconductor treatment according to any one of the above-mentioned application examples, the water-soluble compound (B) may be a water-soluble polymer.

### APPLICATION EXAMPLE 14

The composition for semiconductor treatment according to any one of the above-mentioned application examples may further include an organic acid.

### APPLICATION EXAMPLE 15

In the composition for semiconductor treatment according to any one of the above-mentioned application examples,

the composition for semiconductor treatment may further include potassium and sodium, and

the composition for semiconductor treatment may satisfy the following equation:

M_{K}/M_{Na}=1×10⁻¹ to 1×10⁴

where M_{K} and M_{Na} represent a content (ppm) of the potassium and a content (ppm) of the sodium in the composition for semiconductor treatment, respectively.

### APPLICATION EXAMPLE 16

The composition for semiconductor treatment according to any one of the above-mentioned application examples may have a viscosity at 25° C. of less than 5 mPa·s.

### Advantageous Effects of Invention

Through use of the composition for semiconductor treatment according to the invention, damage due to corrosion to the wiring or the like including tungsten on the object to be treated can be suppressed, and contamination can be efficiently removed from the surface of the object to be treated. In addition, according to the treatment method according to the invention, when the wiring board including tungsten as a wiring material is treated with the composition for semiconductor treatment after the wiring board is subjected to chemical mechanical polishing using the composition containing an iron ion and a peroxide, damage due to corrosion to the wiring or the like including tungsten can be suppressed, and contamination can be efficiently removed from the surface of the wiring board.

### BRIEF DESCRIPTION OF DRAWINGS

FIG. 1 is a sectional view for schematically illustrating a production process for a wiring board to be used in a treatment method according to an embodiment of the invention.

FIG. 2 is a sectional view for schematically illustrating the production process for the wiring board to be used in the treatment method according to the embodiment.

### DESCRIPTION OF EMBODIMENTS

Embodiments of the invention will be described in detail below. The invention is not limited to the following embodiments, and various modifications can be made within the scope of the invention.

### 1. Composition for Semiconductor Treatment

A composition for semiconductor treatment according to an embodiment of the invention is a composition for treating a surface of an object to be treated having arranged thereon a wiring layer including tungsten. The composition for semiconductor treatment includes: a compound (A) having two or more of at least one selected from a group consisting of tertiary amino groups and salts thereof; and a water-soluble compound (B) having a solubility parameter of 10 or more, and has a pH of from 2 to 7.

The composition for semiconductor treatment according to this embodiment may be of a concentrated type intended to be used after being diluted with a liquid medium, such as pure water or an organic solvent, or of a non-dilution type intended to be directly used without being diluted. As used herein, the term “composition for semiconductor treatment” is construed to have a concept including both the concentrated type and the non-dilution type when whether the composition for semiconductor treatment is of the concentrated type or the non-dilution type is not specified.

Such composition for semiconductor treatment can be mainly used as a cleaning agent for removing contaminants, such as particles and organic residues, present on the surface of the object to be treated having arranged thereon the wiring layer including tungsten after the completion of CMP. The components contained in the composition for semiconductor treatment according to this embodiment are described in detail below.

### 1.1. Compound (A)

The composition for semiconductor treatment according to this embodiment includes the compound (A) having two or more of at least one selected from a group consisting of tertiary amino groups and salts thereof (herein also referred to simply as “compound (A)”). In the invention, the “tertiary amino group” refers to —NR¹R², where R¹ and R² each independently represent a hydrocarbon group, and R¹ and R² may be bonded to each other to form a cyclic structure. Herein, the hydrocarbon group represented by each of R¹ and R² has the same meaning as a hydrocarbon group represented by each of R¹ to R³ in the following general formula (1).

The compound (A) has a function of adsorbing onto a surface of a metal on a surface to be treated to reduce corrosion. Therefore, when the compound (A) is added to the composition for semiconductor treatment, damage due to corrosion to wiring or the like including tungsten on the object to be treated can be suppressed. In addition, when the object to be treated is treated with the composition for semiconductor treatment according to this embodiment and is then rinsed with ultrapure water or pure water, the compound (A) is rinsed away therefrom without remaining on the wiring or the like including tungsten, and hence a clean treated surface without contamination can be obtained. Further, the compound (A) also has a function as a pH adjusting agent of adjusting a pH of the composition for semiconductor treatment.

The compound (A) is preferably a water-soluble amine. In the invention, the “water-soluble” refers to a case in which a mass dissolved in 100 g of neutral water at 20° C. is 0.1 g or more. Examples of the water-soluble amine include tertiary amines.

Examples of such tertiary amine include tetramethylethylenediamine, N,N,N′,N′-tetramethyl-1,3-propanediamine, 1,1,4,7,10,10-hexamethyltriethylenetetramine, 2,4,6-tris(dimethylaminomethyl)phenol, 1,8-diazabicyclo(5,4,0)undecene-7,1,5-diazabicyclo(4,3,0)nonene-5,4-dimethylaminopyridine, 2-methylpyrazine, bipyridine, and N,N′-dimethylpiperazine. Those compounds (A) may be used alone or as a mixture thereof.

The content of the compound (A) in the composition for semiconductor treatment according to this embodiment may be appropriately changed depending on materials for a metal wiring material, such as tungsten, an insulating material, such as silicon oxide, and a barrier metal material, such as tantalum nitride or titanium nitride, exposed on the surface of the object to be treated after the CMP, and the composition of a CMP slurry having been used.

Further, the content of the compound (A) may be appropriately changed depending on the degree of dilution of the composition for semiconductor treatment of a concentrated type according to this embodiment. The content of the compound (A) is preferably from 0.0001 part by mass to 10 parts by mass, more preferably from 0.001 part by mass to 5 parts by mass, particularly preferably from 0.05 part by mass to 1 part by mass with respect to 100 parts by mass of a cleaning agent prepared by diluting the composition for semiconductor treatment of a concentrated type or 100 parts by mass of the composition for semiconductor treatment of a non-dilution type. When the content of the compound (A) falls within the above-mentioned range, the component (A) is adsorbed onto a surface of the wiring or the like including tungsten on the object to be treated to protect the surface, to thereby reduce corrosion, with the result that damage to the wiring or the like can be suppressed. In addition, after the object to be treated is rinsed with ultrapure water or pure water, the compound (A) is rinsed away without remaining on the surface of the wiring or the like, and hence a cleaner treated surface without contamination can be obtained.

In the composition for semiconductor treatment according to this embodiment, the tertiary amino group of the compound (A) may form a salt represented by the following general formula (1):

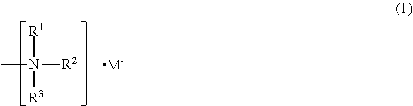

in the formula (1), R¹ to R³ each independently represent a hydrogen atom or a hydrocarbon group, and M⁻ represents an anion, provided that: not all of R¹ to R³ represent hydrogen atoms, and at least two or more of R¹ to R³ represent hydrocarbon groups; and two or more of R¹ to R³ may be bonded to each other to form a cyclic structure.

The hydrocarbon group represented by each of R¹ to R³ in the general formula (1) may be an aliphatic hydrocarbon group, an aromatic hydrocarbon group, an aromatic/aliphatic hydrocarbon group, or an alicyclic hydrocarbon group. In addition, the aliphatic hydrocarbon group and an aliphatic hydrocarbon group of the aromatic/aliphatic hydrocarbon group may be saturated or unsaturated, and may be linear or branched. Examples of such hydrocarbon group may include a linear alkyl group, a branched alkyl group, and a cyclic alkyl group, a linear alkenyl group, a branched alkenyl group, and a cyclic alkyl group, an aralkyl group, and an aryl group.

In general, the alkyl group is preferably a lower alkyl group having 1 to 6 carbon atoms, more preferably a lower alkyl group having 1 to 4 carbon atoms. Examples of such alkyl group may include a methyl group, an ethyl group, a n-propyl group, an iso-propyl group, a n-butyl group, an iso-butyl group, a sec-butyl group, a tert-butyl group, a n-pentyl group, an iso-pentyl group, a sec-pentyl group, a tert-pentyl group, a neopentyl group, a n-hexyl group, an iso-hexyl group, a sec-hexyl group, a tert-hexyl group, a cyclopentyl group, and a cyclohexyl group.

In general, the alkenyl group is preferably a lower alkenyl group having 1 to 6 carbon atoms, more preferably a lower alkenyl group having 1 to 4 carbon atoms. Examples of such alkenyl group may include a vinyl group, a n-propenyl group, an iso-propenyl group, a n-butenyl group, an iso-butenyl group, a sec-butenyl group, and a tert-butenyl group.

In general, the aralkyl group is preferably an aralkyl group having 7 to 12 carbon atoms. Examples of such aralkyl group include a benzyl group, a phenethyl group, a phenylpropyl group, a phenylbutyl group, a phenylhexyl group, a methylbenzyl group, a methylphenethyl group, and an ethylbenzyl group.

In general, the aryl group is preferably an aryl group having 6 to 14 carbon atoms. Examples of such aryl group include a phenyl group, an o-tolyl group, a m-tolyl group, a p-tolyl group, a 2,3-xylyl group, a 2,4-xylyl group, a 2,5-xylyl group, a 2,6-xylyl group, a 3,5-xylyl group, a naphthyl group, and an anthryl group.

An aromatic ring of the aryl group or the aralkyl group may have, as a substituent, for example, a lower alkyl group, such as a methyl group or an ethyl group, or a halogen atom, a nitro group, an amino group, or a hydroxyl group.

Examples of the anion represented by M⁻ in the general formula (1) include an anion derived from an acidic compound and a hydroxide ion (OH⁻).

### 1.2. Compound (B)

The composition for semiconductor treatment according to this embodiment includes the water-soluble compound (B) having a solubility parameter of 10 or more (herein also referred to simply as “compound (B)”). The compound (B) is used for the purpose of acting on the surface of the object to be treated to remove the organic residues.

In the invention, the “solubility parameter (SP value)” refers to a value calculated by a Fedors calculation method. The SP value (δ) may he determined by the following equation (2):

δ=(ΔE/ΔV)^{1/2} (cal/cm³)^{1/2} (2)

in the equation (2), ΔE represents an evaporation energy (cal/mol), and ΔV represents a molar volume (cm³/mol) at 25° C.

In the invention, the “water-soluble compound” refers to a compound in which a mass dissolved in 100 g of neutral water at 20° C. is 0.1 g or more.

The lower limit value of the solubility parameter of the compound (B) is 10 or more, preferably 11 or more, more preferably 12 or more. Meanwhile, the upper limit value of the solubility parameter of the compound (B) is preferably 20 or less, more preferably 16 or less. The compound (B) having a solubility parameter falling within the above-mentioned range can easily interact with the organic residues remaining on the surface of the object to be treated, to thereby solubilize or disperse the organic residues in a treatment agent, and efficiently remove the organic residues from the surface of the object to be treated. Meanwhile, a compound having a solubility parameter below the above-mentioned range has low water solubility, and hence the efficiency of removal of contamination, such as the organic residues, from the surface of the object to be treated is reduced.

Examples of the compound (B) include: compounds each having a solubility parameter of 10 or more, such as methanol, ethanol, n-propanol, 1-propanol, ethylene glycol, propylene glycol, diethylene glycol monoethyl ether, acetonitrile, N,N-dimethylformamide, sulfolane, triacetin, propylene carbonate, ethylene carbonate, and N-methylpyrrolidone; and water-soluble polymers each having a solubility parameter of 10 or more exemplified below.

Examples of the water-soluble polymer having a solubility parameter of 10 or more include, but not limited to:

polyacrylic acid, polymethacrylic acid, polymaleic acid, polyvinylsulfonic acid, polyallylsulfonic acid, polystyrenesulfonic acid, and salts thereof;

a copolymer of a monomer, such as styrene, α-methylstyrene, or 4-methylstyrene, and an acid monomer, such as (meth)acrylic acid or maleic acid, a polymer having repeating units each having an aromatic hydrocarbon group, which is obtained by condensing benzenesulfonic acid, naphthalenesulfonic acid, or the like with formalin, and salts thereof;

vinyl-based synthetic polymers, such as polyvinyl alcohol, polyoxyethylene, polyvinylpyrrolidone, polyvinylpyridine, polyacrylamide, polyvinylformamide, polyethyleneimine, polyvinyloxazoline, polyvinylimidazole, and polyallylamine; and

modified products of natural polysaccharides, such as hydroxyethyl cellulose, carboxymethyl cellulose, and processed starch. The compound (B) is preferably the water-soluble polymer. Those compounds (B) may be used alone or in combination thereof.

The water-soluble polymer serving as the compound (B) may be a homopolymer or a copolymer obtained by copolymerizing two or more types of monomers. As such monomers, for example, a monomer having a carboxyl group, a monomer having a sulfonic acid group, a monomer having a hydroxyl group, a monomer having a polyethylene oxide chain, a monomer having an amino group, and a monomer having a heterocyclic ring may be used.

The water-soluble polymer serving as the compound (B) has a weight-average molecular weight (Mw) of preferably 1,000 or more and 1,500,000 or less, more preferably 3,000 or more and 1,200,000 or less. The term “weight-average molecular weight (Mw)” as used herein refers to a weight-average molecular weight in terms of polyethylene glycol measured by gel permeation chromatography (GPC).

The water-soluble polymer serving as the compound (B) can also adjust the viscosity of the composition for semiconductor treatment. The viscosity of the composition for semiconductor treatment according to this embodiment at 25° C. is preferably less than 5 mPa·s, more preferably 4 mPa·s or less, still more preferably 2 mPa·s or less, further still more preferably 1.2 mPa·s or less, particularly preferably 1 mPa·s or less. When the viscosity of the composition for semiconductor treatment according to this embodiment at 25° C. falls within the above-mentioned range, a sufficient filtration rate can be achieved at the time of purification of the composition for semiconductor treatment through filtration, and throughput enough for practical use can be obtained. In addition, when the viscosity of the composition for semiconductor treatment at 25° C. falls within the above-mentioned range, even in the case where the surface of the object to be treated has irregularities in a treatment step using the composition for semiconductor treatment, the composition can treat the object to be treated by penetrating into the irregularities and being brought into contact with surfaces of the irregularities, and hence the surface of the object to be treated can be treated more homogeneously. When the viscosity of the composition for semiconductor treatment at 25° C. exceeds the above-mentioned range, the composition for semiconductor treatment cannot be supplied stably to the object to be treated owing to an excessively high viscosity in some cases. When the compound (B) is the water-soluble polymer, the viscosity of the composition for semiconductor treatment is determined mostly by the weight average molecular weight and the content of the water-soluble polymer to be added, and hence it is appropriate to adjust the viscosity in consideration of their balance.

As used herein, the “viscosity of the composition for semiconductor treatment” refers to an Ubbelohde viscosity measured in conformity with JIS K2283.

The content of the compound (B) in the composition for semiconductor treatment according to this embodiment may be appropriately changed depending on the surface condition of the object to be treated having arranged thereon the wiring layer including tungsten after the CMP, or the composition of the CMP slurry having been used.

Further, the content of the compound (B) may also be appropriately changed depending on the degree of dilution of the composition for semiconductor treatment of a concentrated type according to this embodiment. The lower limit value of the content of the compound (B) is preferably 0.001 part by mass or more, more preferably 0.01 part by mass or more, and the upper limit value of the content of the compound (B) is preferably 10 parts by mass or less, more preferably 1 part by mass or less, with respect to 100 parts by mass of the cleaning agent prepared by diluting the composition for semiconductor treatment of a concentrated type or 100 parts by mass of the composition for semiconductor treatment of a non-dilution type. When the content of the compound (B) falls within the above-mentioned range, an effect of removing the contaminants, such as particles and organic residues, contained in the CMP slurry from a wiring board is enhanced, and a cleaner treated surface can be easily obtained.

### 1.3. Other Components

The composition for semiconductor treatment according to this embodiment may include potassium, sodium, an organic acid, and other components as required in addition to the above-mentioned components and a liquid medium serving as a main component.

### 1.3.1. Potassium and Sodium

The composition for semiconductor treatment according to this embodiment may further include potassium and sodium at a certain quantitative ratio. In general, as described in, for example, JP 2000-208451 A, an alkali metal, such as sodium or potassium, is recognized as an impurity required to be removed to the extent possible in a semiconductor production process. However, in the invention, the conventional concept is overturned, and it has been found that, in a step of cleaning the object to be treated having arranged thereon the wiring layer including tungsten, the use of the composition for semiconductor treatment including potassium and sodium at a predetermined quantitative ratio rather provides an effect of further improving treatment characteristics without significantly reducing semiconductor characteristics.

In the case where the composition for semiconductor treatment according to this embodiment includes potassium and sodium, the content ratio between potassium and sodium, M_{K}/M_{Na}, where M_{K} and M_{Na} represent the content (ppm) of potassium and the content (ppm) of sodium, respectively, is preferably from 1×10⁻¹ to 1×10⁴, more preferably from 3×10⁻¹ to 7×10³, particularly preferably from 5×10⁻¹ to 5×10³. When the content ratio between potassium and sodium falls within the above-mentioned range, it is considered that tungsten exposed on the surface to be treated can be effectively prevented from being excessively etched and eluted in the semiconductor treatment step.

In the case where the composition for semiconductor treatment of a concentrated type according to this embodiment includes sodium, the content of sodium is preferably from 1×10⁻⁶ ppm to 1×10² ppm, more preferably from 1×10⁻⁵ ppm to 5×10¹ ppm, particularly preferably from 1×10⁻⁴ ppm to 5×10⁰ ppm. In addition, in the case where the composition for semiconductor treatment of a concentrated type according to this embodiment includes potassium, the content of potassium is preferably from 1×10⁻⁴ ppm to 5×10³ ppm, more preferably from 5×10⁻⁴ ppm to 3×10³ ppm, particularly preferably from 1×10⁻³ ppm to 2×10³ ppm.

In the case where the composition for semiconductor treatment of a non-dilution type according to this embodiment includes sodium, the content of sodium is preferably from 1×10⁻⁸ ppm to 1×10² ppm, more preferably from 1×10⁻⁷ ppm to 5×10¹ ppm, particularly preferably from 1×10⁻⁶ ppm to 5×10⁰ ppm. In addition, in the case where the composition for semiconductor treatment of a non-dilution type according to this embodiment includes potassium, the content of potassium is preferably from 1×10⁻⁶ ppm to 5×10³ ppm, more preferably from 5×10⁻⁶ ppm to 3×10³ ppm, particularly preferably from 1×10⁻⁵ ppm to 2×10³ ppm.

When the composition for semiconductor treatment according to this embodiment includes potassium and sodium at the above-mentioned content ratio, and the contents of potassium and sodium fall within the above-mentioned ranges, it is considered that tungsten exposed on the surface to be treated can be effectively prevented from being excessively etched and eluted in the treatment step, and the treatment characteristics can be stably maintained.

The composition for semiconductor treatment according to this embodiment may include potassium and sodium by blending potassium and sodium as water-soluble salts. As such water-soluble salts, for example, sodium and potassium hydroxides, carbonates, ammonium salts, and halides may be used.

In the invention, the content M_{K} (ppm) of potassium and the content M_{Na} (ppm) of sodium in the composition for semiconductor treatment may be measured through quantitative determination of the composition for semiconductor treatment by ICP atomic emission spectrometry (ICP-AES), ICP mass spectrometry (ICP-MS), or atomic absorption spectrometry (AA). As an ICP atomic emission spectrometer, for example, “ICPE-9000 (manufactured by Shimadzu Corporation)” may be used. As an ICP mass spectrometer, for example, “ICPM-8500 (manufactured by Shimadzu Corporation)” or “ELAN DRC PLUS (manufactured by PerkinElmer, Inc.)” may be used. As an atomic absorption spectrometer, for example, “AA-7000 (manufactured by Shimadzu Corporation)” or “ZA3000 (manufactured by Hitachi High-Tech Science Corporation)” may be used.

In the CMP of the object to be treated including tungsten as a wiring material, a CMP slurry containing an iron ion and a peroxide (hydrogen peroxide, potassium iodate, or the like) is used. The iron ion contained in the CMP slurry is liable to be adsorbed onto the surface of the object to be treated, and hence a polished surface is liable to be contaminated with iron. In this case, when the polished surface is cleaned with the composition for semiconductor treatment including potassium and sodium according to this embodiment, generation of a readily soluble salt, such as potassium tungstate or sodium tungstate, is promoted in the cleaning step. With this, it is considered that metal contamination on the wiring board can be reduced, and polishing residues can be efficiently removed while damage to the object to be treated is reduced.

### 1.3.2. Organic Acid

The composition for semiconductor treatment according to this embodiment may include an organic acid. The organic acid preferably has at least one acid group, such as a carboxyl group or a sulfo group. In the invention, the “organic acid” has a concept excluding the above-mentioned compound (B).

Specific examples of the organic acid include citric acid, maleic acid, malic acid, tartaric acid, oxalic acid, malonic acid, succinic acid, ethylenediaminetetraacetic acid, acrylic acid, methacrylic acid, benzoic acid, phenyllactic acid, hydroxyphenyllactic acid, phenylsuccinic acid, naphthalenesulfonic acid, and salts thereof. Those organic acids may be used alone or as a mixture thereof.

An amino acid may be used as the organic acid. Examples of the amino acid include compounds each represented by the following general formula (3):

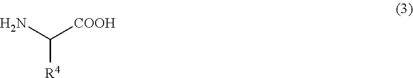

in the general formula (3), R⁴ represents any one selected from the group consisting of: a hydrogen atom; a hydrocarbon group having 1 to 10 carbon atoms; and an organic group having a hetero atom and having 1 to 20 carbon atoms.

Examples of the hydrocarbon group having 1 to 10 carbon atoms represented by R⁴ in the general formula (3) may include a saturated aliphatic hydrocarbon group having 1 to 10 carbon atoms, a saturated cyclic hydrocarbon group having 1 to 10 carbon atoms, and an aromatic hydrocarbon group having 6 to 10 carbon atoms. Of those, a saturated aliphatic hydrocarbon group having 1 to 10 carbon atoms is preferred.

Examples of the organic group having a hetero atom and having 1 to 20 carbon atoms represented by R⁴ in the general formula (3) may include a hydrocarbon group having a carboxyl group and having 1 to 20 carbon atoms, a hydrocarbon group having a hydroxyl group and having 1 to 20 carbon atoms, a hydrocarbon group having an amino group and having 1 to 20 carbon atoms, a hydrocarbon group having a mercapto group and having 1 to 20 carbon atoms, and an organic group having a heterocyclic ring and having 1 to 20 carbon atoms. Those groups may each further have a hetero atom, such as oxygen, sulfur, or a halogen, and part thereof may be substituted by another substituent.

Examples of the compound represented by the general formula (3) may include alanine, arginine, asparagine, aspartic acid, cysteine, glutamine, glutamic acid, glycine, isoleucine, leucine, lysine, methionine, phenylalanine, serine, threonine, tyrosine, valine, tryptophan, histidine, and 2-amino-3-aminopropanoic acid. Those amino acids may be used alone or in combination thereof.

It is also preferred to use a compound represented by the following general formula (4) as the organic acid:

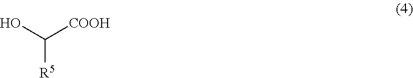

in the general formula (4), R⁵ represents an organic group having 1 to 20 carbon atoms.

Examples of the organic group having 1 to 20 carbon atoms represented by R⁵ in the general formula (4) may include a saturated aliphatic hydrocarbon group having 6 to 20 carbon atoms, an unsaturated aliphatic hydrocarbon group having 6 to 20 carbon atoms, an organic group having a cyclic saturated hydrocarbon group and having 6 to 20 carbon atoms, an organic group having an unsaturated cyclic hydrocarbon group and having 6 to 20 carbon atoms, a hydrocarbon group having a carboxyl group and having 1 to 20 carbon atoms, a hydrocarbon group having a hydroxyl group and having 1 to 20 carbon atoms, a hydrocarbon group having an amino group and having 1 to 20 carbon atoms, and an organic group having a heterocyclic ring group and having 1 to 20 carbon atoms. Of those, an organic group having an unsaturated cyclic hydrocarbon group and having 6 to 20 carbon atoms and a hydrocarbon group having a carboxyl group and having 1 to 20 carbon atoms are preferred, and an organic group having an aryl group and having 6 to 20 carbon atoms and a carboxymethyl group are particularly preferred. The compound represented by the general formula (4) excludes the compound represented by the general formula (3).

Specific examples of the compound represented by the general formula (4) may include hydroxyphenyllactic acid and hydroxymalonic acid. Of those, hydroxyphenyllactic acid is preferred. The compounds listed above may be used alone or in combination thereof.

The content of the organic acid may be appropriately changed depending on the materials for a tungsten wiring material, the insulating material, such as silicon oxide, and the barrier metal material, such as tantalum nitride or titanium nitride, exposed on the surface of the object to be treated after the CMP, and the composition of the CMP slurry having been used.

Further, the content of the organic acid may also be appropriately changed depending on the degree of dilution of the composition for semiconductor treatment of a concentrated type according to this embodiment. The lower limit value of the content of the organic acid is preferably 0.0001 part by mass or more, more preferably 0.0005 part by mass or more, and the upper limit value of the content of the organic acid is preferably 1 part by mass or less, more preferably 0.5 part by mass or less, with respect to 100 parts by mass of the cleaning agent prepared by diluting the composition for semiconductor treatment of a concentrated type or 100 parts by mass of the composition for semiconductor treatment of a non-dilution type. When the content of the organic acid falls within the above-mentioned range, impurities adhering onto the surface of the wiring material can be effectively removed. In addition, excessive progress of etching can be effectively suppressed, and a satisfactory treated surface can be obtained.

### 1.3.3. Liquid Medium

The composition for semiconductor treatment according to this embodiment is a liquid including a liquid medium as a main component. The liquid medium is preferably an aqueous medium including water as a main component. Examples of such aqueous medium include water, a mixed medium of water and an alcohol, and a mixed medium including water and an organic solvent having compatibility with water. Of those, water or a mixed medium of water and an alcohol is preferably used, and water is more preferably used.

### 1.3.4. Other Components

The composition for semiconductor treatment according to this embodiment may include a necessary component at necessary time. For example, the composition for semiconductor treatment may include a pH adjusting agent, a surfactant, or the like.

<pH Adjusting Agent>

The upper limit value of the pH of the composition for semiconductor treatment according to this embodiment is preferably 7 or less, more preferably 6 or less, and the lower limit value of the pH of the composition for semiconductor treatment is preferably 2 or more. When the pH of the composition for semiconductor treatment falls within the above-mentioned range, both a suppressing effect on the corrosion of wiring including tungsten and an organic residue removal effect are enhanced, and a more satisfactory treated surface can be easily obtained.

When the composition for semiconductor treatment according to this embodiment cannot achieve a desired pH by adding the compound (A) or the organic acid described above, a pH adjusting agent may be added additionally so that the pH is adjusted to fall within the above-mentioned range. Examples of the pH adjusting agent include: inorganic acids, such as phosphoric acid, nitric acid, and sulfuric acid; alkali metal hydroxides, such as sodium hydroxide, potassium hydroxide, rubidium hydroxide, and cesium hydroxide; and basic compounds, such as ammonia. Those pH adjusting agents may be used alone or as a mixture thereof.

<Surfactant>

As a surfactant, any known component may be used at necessary time, but a nonionic surfactant or an anionic surfactant may be preferably used. When the surfactant is added, an effect of removing particles and metal impurities contained in the CMP slurry from the wiring board is increased, and a more satisfactory treated surface is obtained in some cases.

Examples of the nonionic surfactant include: polyoxyethylene alkyl ethers, such as polyoxyethylene lauryl ether, polyoxyethylene cetyl ether, polyoxyethylene stearyl ether, and polyoxyethylene oleyl ether; polyoxyethylene aryl ethers, such as polyoxyethylene octyl phenyl ether and polyoxyethylene nonyl phenyl ether; sorbitan fatty acid esters, such as sorbitan monolaurate, sorbitan monopalmitate, and sorbitan monostearate; and polyoxyethylene sorbitan fatty acid esters, such as polyoxyethylene sorbitan monolaurate, polyoxyethylene sorbitan monopalmitate, and polyoxyethylene sorbitan monostearate. The nonionic surfactants shown as examples may be used alone or as a mixture thereof.

Examples of the anionic surfactant include: alkylbenzenesulfonic acids, such as dodecylbenzenesulfonic acid; alkylnaphthalenesulfonic acids; alkyl sulfates, such as lauryl sulfate; polyoxyethylene alkyl ether sulfates, such as polyoxyethylene lauryl sulfate; naphthalenesulfonic acid condensates; alkyliminodicarboxylic acids; and lignosulfonic acid. Those anionic surfactants may each be used in a salt form. In this case, as a counter cation, there are given, for example, a sodium ion, a potassium ion, and an ammonium ion. Of those, an ammonium ion is preferred from the viewpoint of preventing excessive incorporation of potassium and sodium.

In the CMP of the object to be treated including tungsten as a wiring material, the CMP slurry containing an iron ion and a peroxide (hydrogen peroxide, potassium iodate, or the like) is used. The iron ion contained in the CMP slurry is liable to be adsorbed onto the surface of the object to be treated, and hence the surface of the object to be treated is liable to be contaminated with iron. In this case, the iron ion is positively charged, and hence when the anionic surfactant is added to the composition for semiconductor treatment, the contamination with iron on the surface of the object to be treated can be effectively removed in some cases.

The content of the surfactant may be appropriately changed depending on the materials for the metal wiring material, such as tungsten, the insulating material, such as silicon oxide, and the barrier metal material, such as tantalum nitride or titanium nitride, exposed on the surface of the object to be treated after the CMP, and the composition of the CMP slurry having been used.

Further, the content of the surfactant may also be appropriately changed depending on the degree of dilution of the composition for semiconductor treatment of a concentrated type according to this embodiment. The content of the surfactant is preferably 0.001 part by mass or more and 1 part by mass or less with respect to 100 parts by mass of the cleaning agent prepared by diluting the composition for semiconductor treatment of a concentrated type or 100 parts by mass of the composition for semiconductor treatment of a non-dilution type. When the content of the surfactant falls within the above-mentioned range, the particles and the metal impurities contained in the CMP slurry can be efficiently removed from the object to be treated having arranged thereon the wiring layer including tungsten in the treatment step after the completion of the CMP.

### 1.4. Preparation Method for Composition for Semiconductor Treatment

A preparation method for the composition for semiconductor treatment according to this embodiment is not particularly limited, and the composition for semiconductor treatment may be prepared by a known method. Specifically, the composition for semiconductor treatment may be prepared by dissolving the above-mentioned components in the liquid medium, such as water or an organic solvent, followed by filtration. The order of mixing the above-mentioned components and a mixing method therefor are not particularly limited.

In the preparation method for the composition for semiconductor treatment according to this embodiment, it is preferred to control a particle amount through filtration with a depth-type filter or a pleat-type filter as required. Herein, the “depth-type filter” is a high-precision filtration filter also called a deep filtration filter or a volume filtration filter. Examples of such depth-type filter include a filter having a laminate structure in which filtration membranes each having formed therein a large number of pores are laminated on each other, and a filter obtained by winding up fiber bundles. Specific examples of the depth-type filter include Profile II, Nexis NXA, Nexis NXT, Poly-Fine XLD, and Ultipleat Profile (all the items are manufactured by Nihon Pall Ltd.), Depth Cartridge Filter and Wound Cartridge Filter (all the items are manufactured by Advantec), CP filter and BM filter (all the items are manufactured by Chisso Corporation), and SLOPE-PURE, DIA, and MICRO-CILIA (all the items are manufactured by Roki Techno Co., Ltd.).

An example of the pleat-type filter is a high-precision tubular filtration filter obtained by subjecting a precise filtration membrane sheet formed of, for example, non-woven fabric, filter paper, or a metal mesh to pleat processing, followed by forming the membrane sheet into a tubular shape, and sealing a seam of pleats of the sheet in a liquid tight manner and sealing both ends of the resultant tube in a liquid tight manner. Specific examples thereof include HDCII and Poly-Fine II (all the items are manufactured by Nihon Pall Ltd.), PP Pleat Cartridge Filter (manufactured by Advantec), Porous Fine (manufactured by Chisso Corporation), and CERTAIN-PORE and MICRO-PURE (all the items arc manufactured by Roki Techno Co., Ltd.).

It is preferred to use a filter having a rated filtration precision of from 0.01 μm to 20 μm. When a filter having a rated filtration precision falling within the above-mentioned range is used, a filtrate in which the number of particles each having a particle diameter of 20 μm or more measured with a particle counter per mL is 0 can be efficiently obtained. In addition, the number of coarse particles captured by the filter is minimized, and hence a usable period of the filter is extended.

### 2. Cleaning Agent

In the invention, the “cleaning agent” refers to a liquid agent which is prepared by adding a liquid medium to the above-mentioned composition for semiconductor treatment of a concentrated type to dilute the composition for semiconductor treatment, or is the above-mentioned composition for semiconductor treatment of a non-dilution type in itself, and which is actually used for cleaning of the surface to be treated. In general, the above-mentioned composition for semiconductor treatment of a concentrated type is present under a state in which the components are concentrated. Therefore, each user uses the above-mentioned composition for semiconductor treatment of a concentrated type by appropriately diluting the composition with a liquid medium to prepare the cleaning agent, or directly uses the composition for semiconductor treatment of a non-dilution type as the cleaning agent.

In this case, the liquid medium to be used for the dilution has the same meaning as the liquid medium contained in the above-mentioned composition for semiconductor treatment, and may be appropriately selected from the liquid mediums listed above.

As a method of adding the liquid medium to the composition for semiconductor treatment of a concentrated type to dilute the composition for semiconductor treatment, there is given a method involving joining a pipe configured to supply the composition for semiconductor treatment of a concentrated type and a pipe configured to supply the liquid medium to each other on their way to mix the composition for semiconductor treatment and the liquid medium, and supplying the resultant mixed cleaning agent to the surface to be treated. For the mixing, there may be employed a commonly used method, such as: a method involving causing liquids to pass through a narrow passage under a pressurized state to mix the liquids through collision; a method involving filling a filler, such as a glass tube, in the pipe to shunt and separate, and join the flow of the liquids repetitively; or a method involving arranging a blade configured to rotate by power in the pipe.

In addition, as another method of adding the liquid medium to the composition for semiconductor treatment of a concentrated type to dilute the composition for semiconductor treatment, there is given a method involving independently arranging the pipe configured to supply the composition for semiconductor treatment of a concentrated type and the pipe configured to supply the liquid medium, and supplying predetermined amounts of liquids from the respective pipes to the surface to be treated to mix the liquids on the surface to be treated. Further, as still another method of adding the liquid medium to the composition for semiconductor treatment of a concentrated type to dilute the composition for semiconductor treatment, there is given a method involving loading a predetermined amount of the composition for semiconductor treatment of a concentrated type and a predetermined amount of the liquid medium in a container and mixing the composition for semiconductor treatment and the liquid medium, and supplying the resultant mixed cleaning agent to the surface to be treated.

A dilution factor at the time of adding the liquid medium to the composition for semiconductor treatment of a concentrated type to dilute the composition for semiconductor treatment is as follows: 1 part by mass of the composition for semiconductor treatment of a concentrated type is diluted to preferably from 1 part by mass to 500 parts by mass (by from 1 time to 500 times), more preferably from 20 parts by mass to 500 parts by mass (by from 20 times to 500 times), particularly preferably from 30 parts by mass to 300 parts by mass (by from 30 times to 300 times) by adding the liquid medium. The composition for semiconductor treatment of a concentrated type is preferably diluted with the same liquid medium as the above-mentioned liquid medium contained in the composition for semiconductor treatment of a concentrated type. When the composition for semiconductor treatment is in a concentrated state as described above, the composition for semiconductor treatment can be conveyed and stored with a small container as compared to the case of conveying and storing the cleaning agent as it is. As a result, the cost of conveyance and storage can be reduced. In addition, the cleaning agent is purified in a small amount as compared to the case of directly purifying the cleaning agent through filtration or the like, and hence a purification time period can be shortened, and thus mass production can be achieved.

### 3. Treatment Method

A treatment method according to an embodiment of the invention includes a step of subjecting a wiring board including tungsten to treatment with the above-mentioned composition for semiconductor treatment (the above-mentioned cleaning agent). An example of the treatment method according to this embodiment is described in detail below with reference to the drawings.

<Production of Wiring Board>

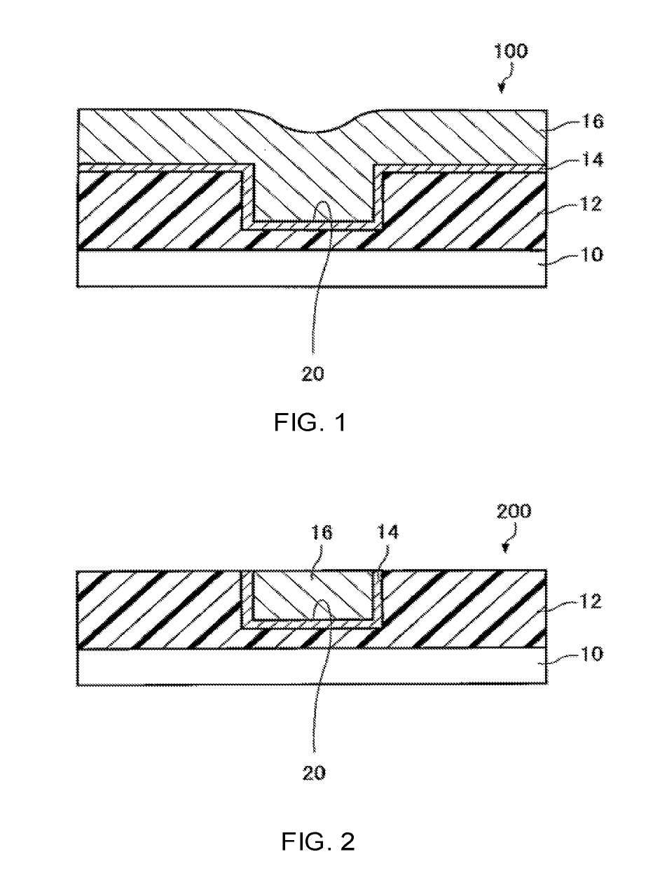

FIG. 1 is a sectional view for schematically illustrating a production process for a wiring board to be used in the treatment method according to this embodiment. The wiring board is produced through the following process.

FIG. 1 is a sectional view for schematically illustrating an object to be treated before CMP treatment. As illustrated in FIG. 1, an object 100 to be treated includes a base 10. The base 10 may be formed of, for example, a silicon substrate and a silicon oxide film formed thereon. Further, the base 10 may have formed thereon a functional device, such as a transistor (not shown).

The object 100 to be treated is formed by sequentially laminating, on the base 10: an insulating film 12 having arranged thereon a depression 20 for wiring; a barrier metal film 14 arranged so as to cover a surface of the insulating film 12 and a bottom and an inside wall surface of the depression 20 for wiring; and a tungsten film 16 filled in the depression 20 for wiring and formed on the barrier metal film 14.

Examples of the insulating film 12 include a silicon oxide film formed by a vacuum process (e.g., a plasma enhanced-TEOS film (PETEOS film), a high density plasma enhanced-TEOS film (HDP film), an silicon oxide film obtained by a thermochemical vapor deposition method), an insulating film called fluorine-doped silicate glass (FSG), a borophosphosilicate film (BPSG film), an insulating film called silicon oxynitride (SiON), and silicon nitride.

As a material for the barrier metal film 14, there are given, for example, tantalum, titanium, cobalt, ruthenium, manganese, and compounds thereof. The barrier metal film 14 is often formed of one type thereof, but two or more types thereof, such as titanium and titanium nitride, may be used in combination.

The tungsten film 16 is required to completely fill the depression 20 for wiring as illustrated in FIG. 1. Therefore, in general, a tungsten film of from 100 Å to 10,000 Å is deposited by a chemical vapor deposition method, a physical vapor deposition method, or an atomic layer deposition method.

Next, in the object 100 to be treated illustrated in FIG. 1, the tungsten film 16 other than a portion buried in the depression 20 for wiring is polished by CMP at high speed until the barrier metal film 14 is exposed (a first polishing step). Further, the barrier metal film 14 exposed on a surface is polished by CMP (a second polishing step). Thus, a wiring board 200 as illustrated in FIG. 2 is obtained.

<Treatment of Wiring Board>

Next, a surface (surface to be treated) of the wiring board 200 illustrated in FIG. 2 is subjected to treatment with the above-mentioned cleaning agent. When the wiring board after the completion of the CMP, on a surface of which a wiring material and a barrier metal material coexist, is treated by the treatment method according to this embodiment, an oxide film and organic residues on the wiring board can be efficiently removed while corrosion of the wiring material and the barrier metal material is suppressed.

The treatment method according to this embodiment is significantly effective when performed on a wiring board including tungsten as a wiring material having been subjected to chemical mechanical polishing using a composition (Fenton's reagent) containing an iron ion and a peroxide described in, for example, JP 10-265766 A. In the CMP of an object to be treated having arranged thereon wiring including tungsten, a CMP slurry containing an iron ion and a peroxide (hydrogen peroxide, potassium iodate, or the like) is often used. The iron ion contained in the CMP slurry is liable to be adsorbed onto a surface of the object to be treated, and hence the surface of the object to be treated is liable to be contaminated with iron. In this case, the contamination with iron can be removed by treating the surface of the object to be treated with dilute hydrofluoric acid. However, a polished surface is liable to be etched and suffer from damage. However, the above-mentioned composition for semiconductor treatment includes the compound (A) and the compound (B), and hence the compound (A) and the iron ion are bonded to each other with an unshared electron pair of the tertiary amino group of the compound (A) and rinsed away in the treatment step. With this, it is considered that metal contamination on the wiring board can be reduced, and polishing residues can be efficiently removed while damage to the object to be treated is reduced.

A treatment method is not particularly limited, but is performed by a method involving bringing the above-mentioned cleaning agent into direct contact with the wiring board 200. Examples of the method of bringing the cleaning agent into direct contact with the wiring board 200 include: a dipping method involving filling a cleaning bath with the cleaning agent and dipping the wiring board thereinto; a spin method involving rotating the wiring board at high speed while causing the cleaning agent to flow down to the wiring board from a nozzle; and a spray method involving spraying the cleaning agent to the wiring board to clean the wiring board. In addition, as a device for performing such method, for example, there are given: a batch treatment device configured to simultaneously treat a plurality of wiring boards accommodated in a cassette; and a single-wafer treatment device configured to treat one wiring board mounted to a holder.

In the treatment method according to this embodiment, the temperature of the cleaning agent is generally set to room temperature. However, the cleaning agent may be warmed within a range not impairing its performance. For example, the cleaning agent may be warmed to from about 40° C. to about 70° C.

In addition, it is preferred to use a treatment method using a physical force in combination with the above-mentioned method of bringing the cleaning agent into direct contact with the wiring board 200. With this, removability of contamination with particles adhering onto the wiring board 200 is improved, and hence a treatment time period can be shortened. Examples of the treatment method using a physical force include scrub cleaning using a cleaning brush and ultrasonic cleaning.

Further, cleaning with ultrapure water or pure water is desirably performed before and/or after cleaning by the treatment method according to this embodiment.

### 4. EXAMPLES

Now, the invention is described by way of Examples, but the invention is by no means limited to these Examples. The terms “part(s)” and “%” in Examples are by mass, unless otherwise stated.

### 4.1. Example 1

### 4.1.1. Preparation of Composition for Semiconductor Treatment (Concentrated Type)

Components were added to a container made of polyethylene at content ratios shown in TABLE 1, an appropriate amount of ion exchanged water was loaded therein, and the resultant was stirred for 15 minutes. Ion exchanged water, potassium hydroxide, and sodium hydroxide were added to the resultant mixture as required so that the total amount of the constituent components was 100 parts by mass. Thus, a composition for semiconductor treatment was prepared so as to have a pH, a K content, and a Na content shown in TABLE 1.

### 4.1.2. Evaluation Test

<Corrosivity Evaluation>

The excellence of corrosivity against wiring including tungsten may be judged through comparative evaluation of an etching rate at the time of immersing a tungsten film wafer in a cleaning agent. It may be judged that a cleaning agent exhibiting a lower etching rate has lower corrosivity against wiring including tungsten.

A tungsten film wafer manufactured by Advantec was cut out into a 5 cm square and used as a test piece. The test piece was immersed in a cleaning agent at 45° C. for 1 hour, followed by washing with water, and drying treatment, the cleaning agent being prepared by adding ion exchanged water to the composition for semiconductor treatment (concentrated type) having been prepared as described above to dilute the composition for semiconductor treatment at a dilution factor shown in TABLE 1. An etching rate of tungsten was evaluated by measuring the weight of the test piece before and after the immersion, and calculating the thickness of a tungsten film having been etched based on a tungsten density of 19.25 g/cm³ and the area of the tungsten film wafer (5 cm×5 cm). The results are shown in TABLE 1. The evaluation criteria are as described below.

(Evaluation Criteria)

The corrosivity was judged as described below.
When an etching rate is less than 0.5 Å/min, the corrosivity is extremely low, and hence the cleaning agent is significantly satisfactory.
When an etching rate is 0.5 Å/min or more and less than 1.2 Å/min, the corrosivity is low, and hence the cleaning agent is usable.
When an etching rate is 1.2 Å/min or more, the corrosivity is high, and hence the cleaning agent is unsatisfactory.

### 4.2. Examples 2, 5, and 6

The evaluation was performed in the same manner as in Example 1 except that a cleaning agent was prepared by changing a used composition for semiconductor treatment to have a composition shown in TABLE 1, and adding ion exchanged water thereto at a dilution factor shown in TABLE 1.

### 4.3. Comparative Example 6

A cleaning agent was prepared in the same manner as in Example 1 except that a used composition for semiconductor treatment was changed to have a composition shown in TABLE 1, and ion exchanged water was added thereto at a dilution factor shown in TABLE 1. In the corrosivity evaluation, a copper film wafer manufactured by Advantec having a diameter of 200 mm was used. The wafer was immersed in the cleaning agent having been prepared as described above at 23° C. for 1 hour, followed by washing with water and drying treatment. An etching rate of a copper film was calculated by measuring the thickness of the film before and after the immersion with a four probe sheet resistance measurement instrument OmniMap RS75 (manufactured by KLA-Tencor Corporation). The results are shown in TABLE 1.

### 4.4. Comparative Example 7

A cleaning agent was prepared in the same manner as in Example 1 except that a used composition for semiconductor treatment was changed to have a composition shown in TABLE 1, and ion exchanged water was added thereto at a dilution factor shown in TABLE 1. In the corrosivity evaluation, a cobalt film wafer manufactured by Advanced Material Technology having a diameter of 200 mm was used. The wafer was immersed in the cleaning agent having been prepared as described above at 23° C. for 1 hour, followed by washing with water and drying treatment. An etching rate of a cobalt film was calculated by measuring the thickness of the film before and after the immersion with a four probe sheet resistance measurement instrument OmniMap RS75 (manufactured by KLA-Tencor Corporation). The results are shown in TABLE 1.

### 4.5. Examples 3, 4, and 7 and Comparative Examples 1 to 5

### 4.5.1. Preparation and Evaluation of Composition for Semiconductor Treatment (Non-Dilution Type)

Components were added to a container made of polyethylene at content ratios shown in TABLE 1, an appropriate amount of ion exchanged water was loaded therein, and the resultant was stirred for 15 minutes. Ion exchanged water, potassium hydroxide, and sodium hydroxide were added to the resultant mixture as required so that the total amount of the constituent components was 100 parts by mass. Thus, a composition for semiconductor treatment was prepared so as to have a pH, a K content, and a Na content shown in TABLE 1.

The evaluation was performed in the same manner as in Example 1 except that the composition for semiconductor treatment (non-dilution type) thus obtained was used directly as a cleaning agent.

### 4.6. Example 8

### 4.6.1. Preparation of Composition for Semiconductor Treatment

A composition for semiconductor treatment was prepared in the same manner as in Example 1.

### 4.6.2. Cleaning Test of Tungsten Wiring Board

(1) Chemical Mechanical Polishing Step

A tungsten film wafer manufactured by Advantec was subjected to one-stage chemical mechanical polishing under the following conditions with a chemical mechanical polishing system “EPO112” manufactured by Ebara Corporation.

<Polishing Conditions>
Aqueous dispersion for chemical mechanical polishing: “W2000” (a slurry containing an iron ion and hydrogen peroxide) manufactured by Cabot Corporation
Polishing pad: “IC1000/SUBA400” manufactured by Rodel-Nitta Company
Platen rotation speed: 70 rpm
Head rotation speed: 71 rpm
Head load: 50 g/cm²
Supply rate of aqueous dispersion for chemical mechanical polishing: 200 mL/min
Polishing time period: 150 seconds

(2) Cleaning Step

The surface of a substrate after the polishing thus obtained was subjected to cleaning on a platen under the following conditions with a cleaning agent prepared by adding ultrapure water (the number of particles each having a particle diameter of 0.3 μm or more was 10 pieces/mL or less, and a pH was 6.5) to the composition for semiconductor treatment having been produced as described above to dilute the composition for semiconductor treatment at a dilution factor shown in TABLE 2. After that, the surface of the substrate was subjected to brush scrub cleaning under the following conditions. After that, the surface of the substrate was subjected to rinse cleaning under the following conditions.

<Cleaning on Platen>
Cleaning agent: the cleaning agent prepared above
Head rotation speed: 71 rpm
Head load: 100 g/cm²
Platen rotation speed: 70 rpm
Supply rate of cleaning agent: 300 mL/min
Cleaning time period: 30 seconds

<Brush Scrub Cleaning>
Cleaning agent: the cleaning agent prepared above
Upper brush rotation speed: 100 rpm
Lower brush rotation speed: 100 rpm
Substrate rotation speed: 100 rpm
Cleaning agent supply amount: 300 mL/min
Cleaning time period: 30 seconds

<Rinse Cleaning>
Cleaning agent: ultrapure water
Upper brush rotation speed: 100 rpm
Lower brush rotation speed: 100 rpm
Substrate rotation speed: 100 rpm
Cleaning agent supply amount: 300 mL/min
Cleaning time period: 10 seconds

### 4.6.3. Evaluation Test

<Reliability Evaluation>

With regard to particles which were not able to be removed in the cleaning step and a particulate defect which resulted in metal contamination, the surfaces of 1,000 tungsten film wafers after the cleaning obtained as described above were each measured for the number of defects on the entire polished surface with a wafer defect inspection system (model “KLA 2351”, manufactured by KLA-Tencor Corporation). A case in which the number of defects on the entire surface of the wafer was more than 250 was evaluated as unsatisfactory. The reliability of the cleaning agent was evaluated by counting the number of wafers evaluated as unsatisfactory in the 1,000 wafers. The results are shown in TABLE 2. The evaluation criteria are as described below.

(Evaluation Criteria)
A case in which the number of wafers evaluated as unsatisfactory is 50 or less in the 1,000 wafers is evaluated as significantly satisfactory and represented by “A”.
A case in which the number of wafers evaluated as unsatisfactory is more than 50 and 100 or less in the 1,000 wafers is evaluated as usable and represented by “B”.
A case in which the number of wafers evaluated as unsatisfactory is more than 100 in the 1,000 wafers is evaluated as unsatisfactory and represented by “C”.

### 4.7. Examples 9 to 14 and Comparative Examples 8 and 9

A cleaning test of a wiring board and an evaluation test were performed in the same manner as in Example 8 except that a composition for semiconductor cleaning was changed to have a composition shown in TABLE 2 to give a cleaning agent having a composition shown in TABLE 2.

### 4.8. Evaluation Results

The compositions and evaluation results of the compositions for semiconductor treatment are shown in TABLES 1 and 2 below.

TABLE 1

| | | | Example | | | | | |
|---|---|---|---|---|---|---|---|---|
| | | | 1 | 2 | 3 | 4 | 5 | 6 |
| Composition for | Compound | 2,4,6-Tris(dimethylamino- | 1.5 | 1.5 | 0.005 | 0.02 | 0.5 | |
| semiconductor | (A) | methyl)phenol | | | | | | |
| treatment | | 1,8-Diazabicyclo(5,4,0)un- | | | | | | 0.317 |
| | | decene-7 | | | | | | |
| | | 1,1,4,7,10,10-Hexamethyl- | | | | | | |
| | | triethylenetetramine | | | | | | |
| | Compound | Propylene glycol (SP value: | 30 | | | | | |
| | (B) | 14.7) | | | | | | |
| | | Sulfolane (SP value: 12.1) | | 3 | | | | |
| | | Polyacrylic acid (SP value: | | | 0.003 | 0.003 | | 0.3 |
| | | 14.0) | | | | | | |
| | | Polyvinylpyrrolidone (SP | | | | | 0.3 | |
| | | value: 12.1) | | | | | | |
| | Acid | Phosphoric acid | 1.24 | 1.26 | 0.005 | | 0.408 | 0.148 |
| | | Tartaric acid | | | | 0.01 | | |
| | Base | Monoethanolamine | | | | | | |
| | | Choline | | | | | | |
| | | Ammonia | | | | | | |
| | Water | Ion exchanged water | Balance | Balance | Balance | Balance | Balance | Balance |
| | Contents | M_{K} (ppm) | 5.0 × 10⁰ | 1.0 × 10¹ | 1.0 × 10⁻¹ | 5.0 × 10⁻² | 2.0 × 10⁰ | 1.0 × 10⁰ |
| | of K and | M_{Na} (ppm) | 1.0 × 10⁰ | 1.0 × 10⁻² | 2.0 × 10⁻¹ | 5.0 × 10⁻² | 2.0 × 10⁰ | 1.0 × 10⁻¹ |
| | Na | M_{K/}Mₙₐ | 5.0 × 10⁰ | 1.0 × 10³ | 5.0 × 10⁻¹ | 1.0 × 10⁰ | 1.0 × 10⁰ | 1.0 × 10¹ |

| | | | | | | | |
|---|---|---|---|---|---|---|---|
| | pH | 5 | 5 | 4 | 6 | 5.1 | 5.9 |
| Production | Dilution factor | 300 | 300 | 1 | 1 | 100 | 100 |
| conditions | | | | | | | |
| Evaluation | Type of object to be treated | W film | W film | W film | W film | W film | W film |
| | Treatment temperature (° C.) | 45 | 45 | 45 | 45 | 45 | 45 |
| | Corrosivity: etching rate (Å/min) | 0.2 | 0.3 | 0.1 | 0.8 | 0.3 | 0.8 |

| | | | Example | Comparative Example | | | |
|---|---|---|---|---|---|---|---|
| | | | 7 | 1 | 2 | 3 | 4 |
| Composition for | Compound | 2,4,6-Tris(dimethylamino- | | | | | |
| semiconductor | (A) | methyl)phenol | | | | | |
| treatment | | 1,8-Diazabicyclo(5,4,0)un- | | | | | |
| | | decene-7 | | | | | |
| | | 1,1,4,7,10,10-Hexamethyl- | 0.01 | | | | |
| | | triethylenetetramine | | | | | |
| | Compound | Propylene glycol (SP value: | | | | | |
| | (B) | 14.7) | | | | | |
| | | Sulfolane (SP value: 12.1) | 0.01 | | | | |
| | | Polyacrylic acid (SP value: | | | | 0.003 | 0.003 |
| | | 14.0) | | | | | |
| | | Polyvinylpyrrolidone (SP | | | | | |
| | | value: 12.1) | | | | | |
| | Acid | Phosphoric acid | 0.008 | | | | |
| | | Tartaric acid | | | | | |
| | Base | Monoethanolamine | | | | 0.003 | |
| | | Choline | | | | | 0.001 |
| | | Ammonia | | | 1 | | |
| | Water | Ion exchanged water | Balance | 100 | Balance | Balance | Balance |
| | Contents | M_{K} (ppm) | 1.0 × 10⁻¹ | No | No | 5.0 × 10⁻² | 5.0 × 10⁻² |
| | of K and | | | addition | addition | | |
| | Na | M_{Na} (ppm) | 5.0 × 10⁻² | No | No | 5.0 × 10⁻² | 5.0 × 10⁻² |
| | | | | addition | addition | | |
| | | M_{K/}Mₙₐ | 2.0 × 10⁰ | — | — | 1.0 × 10⁰ | 1.0 × 10⁰ |

| | | | | | | |
|---|---|---|---|---|---|---|
| | pH | 6.1 | 6 | 11.6 | 6 | 5.9 |
| Production | Dilution factor | 1 | 1 | 1 | 1 | 1 |
| conditions | | | | | | |
| Evaluation | Type of object to be treated | W film | W film | W film | W film | W film |
| | Treatment temperature (° C.) | 45 | 45 | 45 | 45 | 45 |
| | Corrosivity: etching rate (Å/min) | 0.9 | 1.2 | 3.3 | 1.4 | 1.2 |

| | | | Comparative Example | | |
|---|---|---|---|---|---|
| | | | 5 | 6 | 7 |
| Composition for | Compound | 2,4,6-Tris(dimethylamino- | 0.01 | 0.5 | 0.5 |
| semiconductor | (A) | methyl)phenol | | | |
| treatment | | 1,8-Diazabicyclo(5,4,0)un- | | | |
| | | decene-7 | | | |
| | | 1,1,4,7,10,10-Hexamethyl- | | | |
| | | triethylenetetramine | | | |
| | Compound | Propylene glycol (SP value: | | | |
| | (B) | 14.7) | | | |
| | | Sulfolane (SP value: 12.1) | | | |
| | | Polyacrylic acid (SP value: | 0.003 | | |
| | | 14.0) | | | |
| | | Polyvinylpyrrolidone (SP | | 0.3 | 0.3 |
| | | value: 12.1) | | | |
| | Acid | Phosphoric acid | | 0.408 | 0.408 |
| | | Tartaric acid | | | |
| | Base | Monoethanolamine | | | |
| | | Choline | | | |
| | | Ammonia | | | |
| | Water | Ion exchanged water | Balance | Balance | Balance |
| | Contents | M_{K} (ppm) | 5.0 × 10⁻² | 2.0 × 10⁰ | 2.0 × 10⁰ |
| | of K and | M_{Na} (ppm) | 5.0 × 10⁻² | 2.0 × 10⁰ | 2.0 × 10⁰ |
| | Na | M_{K/}Mₙₐ | 1.0 × 10⁰ | 1.0 × 10⁰ | 1.0 × 10⁰ |

| | | | | |
|---|---|---|---|---|
| | pH | 9.8 | 5.1 | 5.1 |
| Production | Dilution factor | 1 | 100 | 100 |
| conditions | | | | |
| Evaluation | Type of object to be treated | W film | Cu film | Co film |
| | Treatment temperature (° C.) | 45 | 23 | 23 |
| | Corrosivity: etching rate (Å/min) | 1.8 | 2.9 | 1.8 |

TABLE 2

| | | | Example | | | | |
|---|---|---|---|---|---|---|---|
| | | | 8 | 9 | 10 | 11 | 12 |
| Composition for | Compound | 2,4,6-Tris(dimethylaminomethyl)phenol | 1.5 | 1.5 | 0.005 | 0.02 | 0.5 |
| semiconductor | (A) | 1,8 -Diazabicyclo(5,4,0)undecene-7 | | | | | |
| treatment | | 1,1,4,7,10,10-Hexamethyltriethylene- | | | | | |
| | | tetramine | | | | | |
| | Compound | Propylene glycol (SP value: 14.7) | 30 | | | | |
| | (B) | Sulfolane (SP value: 12.1) | | 3 | | | |
| | | Polyacrylic acid (SP value: 14.0) | | | 0.003 | 0.003 | |
| | | Polyvinylpyrrolidone (SP value: 12.1) | | | | | 0.3 |
| | Acid | Phosphoric acid | 1.24 | 1.26 | 0.005 | | 0.408 |
| | | Tartaric acid | | | | 0.01 | |
| | Base | Monoethanolamine | | | | | |
| | | Choline | | | | | |
| | | Ammonia | | | | | |
| | Water | Ion exchanged water | Balance | Balance | Balance | Balance | Balance |
| | Contents | M_{K} (ppm) | 5.0 × 10⁰ | 1.0 × 10¹ | 1.0 × 10⁻¹ | 5.0 × 10⁻² | 2.0 × 10⁰ |
| | of K and | M_{Na} (ppm) | 1.0 × 10⁰ | 1.0 × 10⁻² | 2.0 × 10⁻¹ | 5.0 × 10⁻² | 2.0 × 10⁰ |
| | Na | M_{K/}Mₙₐ | 5.0 × 10⁰ | 1.0 × 10³ | 5.0 × 10⁻¹ | 1.0 × 10⁰ | 1.0 × 10⁰ |

| | | | | | | |
|---|---|---|---|---|---|---|
| | pH | 5 | 5 | 4 | 6 | 5.1 |
| Production | Dilution factor | 300 | 300 | 1 | 1 | 100 |
| conditions | | | | | | |
| Evaluation item | Reliability evaluation | A | A | A | A | A |

| | | | Example | | Comparative Example | |
|---|---|---|---|---|---|---|
| | | | 13 | 14 | 8 | 9 |
| Composition for | Compound | 2,4,6-Tris(dimethylaminomethyl)phenol | | | | |
| semiconductor | (A) | 1,8 -Diazabicyclo(5,4,0)undecene-7 | 0.317 | | | |
| treatment | | 1,1,4,7,10,10-Hexamethyltriethylene- | | 0.01 | | |
| | | tetramine | | | | |
| | Compound | Propylene glycol (SP value: 14.7) | | | | |
| | (B) | Sulfolane (SP value: 12.1) | | 0.01 | | |
| | | Polyacrylic acid (SP value: 14.0) | 0.3 | | | |
| | | Polyvinylpyrrolidone (SP value: 12.1) | | | | |
| | Acid | Phosphoric acid | 0.148 | 0.008 | | |
| | | Tartaric acid | | | | |
| | Base | Monoethanolamine | | | | |
| | | Choline | | | | |
| | | Ammonia | | | | 1 |
| | Water | Ion exchanged water | Balance | Balance | 100 | Balance |
| | Contents | M_{K} (ppm) | 1.0 × 10⁰ | 1.0 × 10⁻¹ | No | No |
| | of K and | | | | addition | addition |
| | Na | M_{Na} (ppm) | 1.0 × 10⁻¹ | 5.0 × 10⁻² | No | No |
| | | | | | addition | addition |
| | | M_{K/}Mₙₐ | 1.0 × 10¹ | 2.0 × 10⁰ | — | — |

| | | | | | |
|---|---|---|---|---|---|
| | pH | 5.9 | 6.1 | 6 | 11.6 |
| Production | Dilution factor | 100 | 1 | 1 | 1 |
| conditions | | | | | |
| Evaluation item | Reliability evaluation | B | B | C | C |

The numerical values for each component shown in TABLES 1 and 2 above are represented by part(s) by mass. In each of Examples and Comparative Examples, the total amount of the components is 100 parts by mass, with the balance being ion exchanged water. In addition, details about the components shown in TABLES 1 and 2 above are as described below.

<Compound (A)>
2,4,6-Tris(dimethylaminomethyl)phenol: manufactured by Kayaku Akzo Co., Ltd., product name: “TAP”
1,8-Diazabicyclo(5,4,0)undecene-7: manufactured by San-Apro Ltd., product name: “DBU”
1,1,4,7,10,10-Hexamethyltriethylenetetramine: manufactured by Koei Chemical Company, Ltd., product name: “hexamethyltriethylenetetramine”

<Compound (B)>
Propylene glycol (SP value: 14.7): manufactured by Wako Pure Chemical Industries, Ltd.
Sulfolane (SP value: 12.1): manufactured by Sankyo Chemical Co., Ltd.
Polyacrylic acid (Mw=55,000, SP value: 14.0): manufactured by Toagosei Co., Ltd., product name: “JURYMER AC-10L”
Polyvinylpyrrolidone (Mw=45,000, SP value: 12.1): manufactured by DKS Co., Ltd., product name: “PITZCOL K-30”

<Acid>
Phosphoric acid: manufactured by Rasa Industries, Ltd.
Tartaric acid: manufactured by Tokyo Chemical Industry Co., Ltd.

<Base>
Monoethanolamine: manufactured by Hayashi Pure Chemical Ind., Ltd.
Choline: manufactured by Tama Chemicals Co., Ltd.
Ammonia: manufactured by Mitsubishi Gas Chemical Company, Inc.

As apparent from TABLE 1 above, it was revealed that the compositions for semiconductor treatment according to Examples 1 to 7 each had an excellent property of causing little corrosion of tungsten, and hence were each useful for suppressing damage to wiring or the like including tungsten on an object to be treated.

As apparent from TABLE 2 above, it was revealed that, according to the cleaning method involving using each of the compositions for semiconductor treatment according to Examples 8 to 14, when the tungsten film wafer is cleaned with the composition for semiconductor treatment after the tungsten film wafer is subjected to chemical mechanical polishing using the composition for chemical mechanical polishing containing an iron ion and a peroxide, damage due to corrosion to the tungsten film wafer was able to be suppressed, and contamination was able to be efficiently removed from the surface of the tungsten film wafer.

The invention is not limited to the above-described embodiments, and various modifications can be made. The invention includes configurations that are substantially the same (for example, in function, method, and results, or in objective and effects) as the configurations described in the embodiments. The invention also includes configurations in which non-essential elements described in the embodiments are replaced by other elements. The invention also includes configurations having the same effects as those of the configurations described in the embodiments, or configurations capable of achieving the same objectives as those of the configurations described in the embodiments. The invention further includes configurations obtained by adding known art to the configurations described in the embodiments.

### REFERENCE SIGNS LIST

10: base, 12: insulating film, 14: barrier metal film, 16: tungsten film, 20: depression for wiring, 100: object to be treated, and 200: wiring board

1. A treatment method, comprising:
subjecting a wiring board containing tungsten as a wiring material to chemical mechanical polishing by using a composition containing an iron ion and a peroxide; and
subjecting the wiring board to a treatment which uses a composition for semiconductor treatment, the composition for semiconductor treatment having a pH of from 2 to 7 and containing a compound (A) having two or more of at least one selected from the group consisting of a tertiary amino group and a salt thereof, and a water-soluble compound (B) having a solubility parameter of 10 or more.

2. The treatment method according to claim 1, further comprising:
diluting the composition for semiconductor treatment by from 20 times to 500 times.

3. The treatment method according to claim 1, further comprising:
adjusting a viscosity of the composition for semiconductor treatment at 25° C. to less than 5 mPa·s.

4. The treatment method according to claim 1, further comprising:
filtering the composition for semiconductor treatment with a depth-type filter or a pleat-type filter.

5. The treatment method according to claim 1, wherein subjecting the wiring board to a treatment which uses a composition for semiconductor treatment includes any one of:
filling a cleaning bath with the composition for semiconductor treatment and dipping the wiring board thereinto;
rotating the wiring board at a high speed while causing the composition for semiconductor treatment to flow down to the wiring board from a nozzle; and
spraying the composition for semiconductor treatment on the wiring board to clean the wiring board.

6. The treatment method according to claim 1, comprising: subjecting the wiring board to a treatment using a physical force, as the step of subjecting the wiring board to a treatment which uses a composition for semiconductor treatment.

7. The treatment method according to claim 1, further comprising: cleaning the wiring board with ultrapure water or pure water.

8. The treatment method according to claim 1, wherein the water-soluble compound (B) is a water-soluble polymer.

9. The treatment method according to claim 1, wherein the composition for semiconductor treatment further contains at least one selected from the group consisting of an organic acid and phosphoric acid.

10. The treatment method according to claim 1, wherein
the composition for semiconductor treatment contains potassium and sodium, and
the composition for semiconductor treatment satisfies the following equation:
M_{K}/M_{Na}=1×10⁻¹ to 1×10⁴
where M_{K} and M_{Na} represent a content (ppm) of the potassium and a content (ppm) of the sodium in the composition for semiconductor treatment, respectively.

11. A composition for semiconductor treatment of a concentrated type for treating a surface of an object having arranged thereon wiring containing tungsten, the composition comprising:
a compound (A) having two or more of at least one selected from the group consisting of a tertiary amino group and a salt thereof; and
a water-soluble compound (B) having a solubility parameter of 10 or more,
wherein the composition has a pH of from 2 to 7.

12. The composition according to claim 11, which is used after being diluted by from 1 time to 500 times.

13. A composition for semiconductor treatment of a non-dilution type for treating a surface of an object having arranged thereon wiring containing tungsten, the composition comprising:
a compound (A) having two or more of at least one selected from the group consisting of a tertiary amino group and a salt thereof; and
a water-soluble compound (B) having a solubility parameter of 10 or more,
wherein the composition has a pH of from 2 to 7.

14. The composition according to claim 13, wherein the water-soluble compound (B) is a water-soluble polymer.

15. The composition according to claim 13, further comprising an organic acid.

16. The composition according to claim 13, further comprising
potassium and sodium,
wherein the composition satisfies the following equation:
M_{K}/M_{Na}=1×10⁻¹ to 1×10⁴
where M_{K} and M_{Na} represent a content (ppm) of the potassium and a content (ppm) of the sodium in the composition, respectively.

17. The composition according to claim 13, which has a viscosity at 25° C. of less than 5 mPa·s.
